(19) United States
(12) Patent Application Publication
(10) Pub. No.: US 2019/0056186 A1
(43) Pub. Date: Feb. 21, 2019

(54) Cooling device and method for producing the cooling device

(71) Applicant: Mahle International GmbH, Stuttgart (DE)

(72) Inventors: Matthias Tuerpe, Marbach a.N. (DE); Bernd Gruenenwald, Nuertingen (DE); Oliver Mamber, Markroeningen (DE)

(21) Appl. No.: 15/998,811

(22) Filed: Aug. 16, 2018

(30) Foreign Application Priority Data
Aug. 16, 2017 (DE) 102017214267.7

(51) Int. Cl. F28F 21/04; H05K 7/20

(52) U.S. Cl. CPC F28F 21/04; F28F 2275/025; H05K 7/209

(57) ABSTRACT

A cooling device for cooling power electronics may include a heat-dissipating cooling plate and a contacting surface arranged thereon. The contacting surface may include multiple conductors arranged thereon configured to fix and contact a power electronics. The contacting surface may be electrically insulated from the heat-dissipating cooling plate. Between the heat-dissipating cooling plate and the contacting surface at least one organic intermediate layer may be arranged. The at least one organic intermediate layer may be fixed to the heat-dissipating cooling plate in a firmly bonded manner.

### CROSS-REFERENCE TO RELATED APPLICATIONS

This application claims priority to German Patent Application No. DE 10 2017 214 267.7, filed on Aug. 16, 2017, the contents of which are hereby incorporated by reference in its entirety.

### TECHNICAL FIELD

The invention relates to a cooling device for cooling power electronics. The invention also relates to a method for producing the cooling device.

### BACKGROUND

Power electronics is usually arranged on an Al₂O₃ ceramic conductor support that is copper-coated on both sides—a so-called DCB substrate (direct copper bonded conductor support) and on a top side soldered to the same. After a function check of the power electronics the DCB substrate is joined to a copper plate on a bottom side by way of a soldering method below 450° C. The heat generated in the DCB substrate by the power electronics can be dissipated through the copper plate and the power electronics cooled in this way. For reasons of cost and weight, the copper plate is increasingly replaced with an aluminium plate—or aluminium alloy plate. However, a soldering method between the copper-coated DCB substrate and the aluminium plate is not easily possible because of an oxide layer on the aluminium plate.

Some approaches for solving the mentioned problem are known from the prior art. Accordingly, a nickel plate in a controlled atmosphere and subsequently the DCB substrate are soldered for example onto the aluminium plate by way of a known soldering method. Disadvantageously, the nickel plate has a lower heat conductivity than the aluminium plate and soldering-on the nickel plate requires additional expenditure. Attempts are made, furthermore, to braze the DCB substrate onto the aluminium plate for example by way of a brazing method at approximately 600° C. using an Al—Si solder. However, the high process temperature results in internal stresses and damage in the DCB plate during the cooling. Soldering the DCB substrate onto the aluminium plate is also possible only at a high process temperature and for small geometries—for example contacts. Thus, none of these approaches results in a satisfactory solution to the described problem.

### SUMMARY

The object of the invention therefore is to provide a cooling device and a method for producing the cooling device, with which the mentioned disadvantages are overcome.

According to the invention, this object is solved through the subject matter of the independent claim(s). Advantageous embodiments are subject of the dependent claim(s).

The present invention is based on the general idea of replacing a soldering and a brazing method during the production method of a cooling device for cooling power electronics with an alternative joining method. The generic cooling device in this case comprises a heat-dissipating cooling plate on which a contacting surface with multiple conductors for fixing and for contacting the power electronics is fixed. Here, the contacting surface is electrically insulated from the heat-dissipating cooling plate. According to the invention, at least one organic intermediate layer is arranged between the heat-dissipating cooling plate and the contacting surface, which is fixed to the heat-dissipating cooling plate in a firmly bonded manner.

The heat-dissipating cooling plate in this case can consist of copper or of aluminium or of an aluminium alloy or of an aluminium-plastic composite. The heat-dissipating cooling plate has a high heat conductivity so that the heat generated in the power electronics can be dissipated through the heat-dissipating cooling plate. The contacting surface can consist of copper and comprises multiple conductors on which the power electronics is fixed in an electrically conductive manner for example by way of a soldering method below 450° C. Here, the power electronics can comprise multiple electronic units—such as for example transistors, transducers or capacitors—which are electrically interconnected in this way.

Practically, the cooling plate is electrically insulated from the contacting surface so that the leakage currents between the power electronics and the usually electrically conductive cooling plate are avoided.

According to the invention, the at least one organic intermediate layer is fixed to the cooling plate in a firmly bonded manner. A firmly bonded connection between the cooling plate and the organic intermediate layer in this case is created by atomic or molecular forces and is not disconnectable without destroying the organic intermediate layer. The organic intermediate layer can for example be applied to the cooling plate by way of a coating method or fixed to the cooling plate in the form of a thin film with a heat supply in a firmly bonded manner. On the organic intermediate layer, further components of the cooling device can be fixed, wherein the organic intermediate layer has a low process temperature and the cooling device can consequently be produced at a lower process temperature. Because of this, in particular internal stresses in the further components of the cooling device are advantageously avoided. In addition to this, the number of the production steps during the production of the cooling device are reduced because of the organic intermediate layer, as a result of which cost and time advantages materialise.

In a particularly advantageous further development of the cooling device according to the invention it is provided that the organic intermediate layer is an adhesive layer and that the cooling device comprises a ceramic plate that is fixed to the adhesive layer. Here, the contacting surface is fixed to the ceramic plate in a firmly bonded manner and electrically insulated from the heat-dissipating cooling plate by the ceramic plate. Advantageously, fixing the ceramic plate on the adhesive layer can be carried out at a process temperature below 250° C., as a result of which internal stresses in the ceramic plate and in the contacting surface are advantageously avoided. In addition, conventionally necessary production steps are no longer required, as a result of which the production expenditure and the manufacturing costs are reduced.

The ceramic plate can for example be an Al₂O₃ ceramic plate, on which the contacting surface is fixed in a firmly bonded manner. The contacting surface can for example be a conductor support produced from a thick copper film by way of a stamping method—a so-called leadframe—with multiple conductors, which is fixed to the ceramic plate by way of a bonding method or by way of a joining method. Alternatively, the ceramic plate can be reduced with the copper contacting surface in an already known production method of a so-called DCB substrate with reduced expenditure and cost-effectively. Compared with a conventional ceramic plate copper-coated on both sides—a DCB substrate—the material and consequently also the production costs can be reduced here. Alternatively, the ceramic plate can have a copper layer facing away from the contacting surface. Such a ceramic plate with the copper layer and with the contacting surface corresponds to a conventional ceramic plate copper-coated on both sides—a DCB substrate—and is cost-effectively available on the market. The ceramic conductor support is practically fixed with the copper layer on the adhesive layer so that the contacting surface is electrically insulated from the copper layer and from the heat-dissipating cooling plate by the ceramic plate.

In an alternative further development of the cooling device according to the invention it is advantageously provided that the organic intermediate layer is an insulating layer and that the contacting surface is electrically insulated from the heat-dissipating cooling plate by the insulating layer. The contacting surface can then be directly fixed to the insulating layer as a result of which additional layers—and in particular the ceramic plate—are no longer required and the cooling device can be constructed in a more compact manner. Furthermore, the number of production steps when producing the cooling device can be reduced as a result of which substantial cost and time advantages materialise. In order to make possible a faster dissipation of the heat generated in the power electronics it is advantageously provided that the heat-dissipating cooling plate and/or the insulating layer have a three-dimensional structure.

In a further development of the solution according to the invention it is preferably provided that the insulating layer comprises parylene or consists of the same. Parylenes have a dielectric strength up to 5,000 volt and a surface resistance of approximately 10¹⁵ ohm with a layer thickness of 50 μm. Because of the insulating layer of parylene, the contacting surface can be electrically insulated from the heat-dissipating and usually electrically conductive cooling plate and because of this leakage currents avoided. Parylenes are additionally stable up to 350° C. and have a comparatively high heat conductivity. The heat generated in the power electronics can consequently be dissipated to the cooling plate through the insulating layer of parylene and the insulating layer of parylene remains stable even with a high heat generation in the power electronics. Furthermore, parylenes have a low thermal expansion so that internal stresses in the insulating layer and in the contacting surface can be avoided.

Advantageously it is provided that the contacting surface is fixed to the insulating layer, preferably by a wet coating method or by a physical vapour deposition. Accordingly, the contacting surface can be applied to the insulating layer for example by way of a printing method. Advantageously, the contacting surface is produced in this manner in the sole manufacturing step and fixed to the insulating layer, as a result of which the production costs and the production expenditure are reduced. Alternatively, the contacting surface can be a conductor support which is fixed to the insulating layer using an organic adhesive coating. The conductor support—a so-called leadframe—can be produced for example from a thick copper film by way of a stamping method. Advantageously, larger currents can flow through the leadframe so that altogether the heat generation in the power electronics is reduced.

Furthermore it is advantageously provided that on the contacting surface at least one electronic unit is fixed, preferably by way of a soldering method. The electronic unit—for example a transistor, a transducer or a capacitor—can be electrically interconnected to other electronic units through the conductors of the contacting surface. In this way, a so-called SMD component (surface mounted device) is essentially produced. For protecting the at least one electronic unit, the cooling device can comprise a protective coating which protects the at least one electronic unit from mechanical damage and external influences. Preferably, the protective coating consists of parylene which is chemically resistant and electrically insulating. Alternatively or additionally, the protective coating can also be arranged on the intermediate layer or on the contacting surface and protect the same from mechanical damage and external influences.

In the cooling device according to the invention, the contacting surface is fixed to the cooling plate over a large area so as to reduce expenditure. The cooling device according to the invention makes possible an efficient dissipation of the heat generated in the power electronics and can be produced in a more compact, more cost-effective and quicker manner.

The invention also relates to a method for producing the cooling device described above. In the method according to the invention, an organic intermediate layer is applied to a heat-dissipating cooling plate and subsequently a contacting surface with multiple conductors for fixing and for contacting power electronics fixed to the heat-dissipating cooling plate. Here, the organic intermediate layer can be applied to the cooling plate for example by way of a coating method or, with a heat supply, fixed to the cooling plate in a firmly bonded manner in the form of a thin film. Further components of the cooling device—among others also the contacting surface—can subsequently be fixed to the organic intermediate layer. The organic intermediate layer can be fixed to the cooling blade at a low process temperature and consequently the cooling device produced at a low process temperature. In this way, internal stresses in the further components of the cooling device can be advantageously avoided.

Advantageously it is provided that the organic intermediate layer is applied to the heat-dissipating cooling plate in the form of an adhesive layer and that by means of the adhesive layer a ceramic plate with the contacting surface is fixed with a heat supply on the heat-dissipating cooling plate. Advantageously, the ceramic plate can already be fixed to the adhesive layer at a process temperature below 250° C., as a result of which internal stresses in the ceramic plate and in the contacting surface are advantageously avoided. The ceramic plate can be produced for example from Al₂O₃ and the contacting surface of copper fixed to the ceramic plate by way of an already known production method of a so-called DCB substrate with reduced expenditure and cost-effectively. A copper layer facing away from the contacting surface can also be applied to the ceramic plate and the ceramic plate be produced as a conventional DCB substrate. Through the ceramic plate, the contacting surface is electrically insulated from the usually electrically contacting cooling plate so that leakage currents between the power electronics and the cooling plate are advantageously avoided.

Alternatively, it is advantageously provided that the organic intermediate layer is applied to the heat-dissipating cooling plate in the form of an insulating layer, preferably of parylene and that the contacting surface is electrically insulated from the heat-dissipating cooling plate by the insulating layer. In this way, the contacting surface can be directly applied to the insulating layer and additional layers—and in particular the ceramic plate—can be omitted. Accordingly, the cooling device can be constructed in a more compact manner and the number of the production steps can be advantageously reduced. Preferably, the insulation layer of parylene, which has a high dielectric strength and a high surface resistance is applied to the cooling plate. By way of the insulating layer of parylene, the contacting surface is electrically insulated from the heat-dissipating and usually electrically conductive cooling plate and the leakage currents are advantageously avoided. Furthermore, parylenes remain stable up to 350° C. and have a comparatively high heat conductivity so that the heat generated in the power electronics is quickly dissipated to the cooling plate. Furthermore, parylenes have a low heat expansion and because of this, internal stresses in the insulating layer and in the contacting surface are advantageously avoided even with higher heat fluctuations because of this.

The insulating layer can be advantageously applied to the heat-dissipating cooling plate by a chemical vacuum vapour deposition. Here, polymers, preferably parylenes, are deposited from a gas phase onto the cooling plate in a controlled atmosphere.

Advantageously, a pattern mask can be arranged on the heat-dissipating cooling plate prior to the chemical vacuum vapour deposition. By way of the pattern mask, the polymers are applied to the cooling plate in a structured manner. Following the chemical vacuum vapour deposition, the pattern mask can be—automatically or manually—removed from the heat-dissipating cooling plate. Alternatively to this, the insulating layer can be structured after the chemical vacuum vapour deposition. Preferably, the insulating layer is structured by removing the insulating layer from the cooling plate by a laser in regions.

In a further development of the method according to the invention it is provided that the contacting surface is applied to the insulating layer by way of a wet coating method or by way of a physical vapour deposition. Accordingly, the contacting surface can be applied to the insulating layer for example by way of a printing method. In this way, the contacting surface is produced in a single production step and fixed to the insulation layer. Both the production costs and also the production expenditure are substantially reduced because of this.

Alternatively to this it is provided that the contacting surface in the form of a conductor support is fixed to the insulating layer by means of an organic adhesive coating. The conductor support—a so-called leadframe—can be produced by way of a stamping method for example from a thick copper film. The conductor support advantageously conducts larger currents and the heat generation in the power electronics is substantially reduced because of this. In order to be able to fix the conductor support on the insulating layer free of defects, the insulating layer can be pretreated prior to fixing the adhesive coating on the insulating layer. Preferably, the insulating layer is pre-treated by way of a plasma pre-treatment method or by way of a bonding agent application method in order to improve the bonding properties of the insulating layer.

Advantageously it is provided that prior to fixing the contacting surface on the cooling plate at least one electronic unit is fixed to the contacting surface preferably by way of a soldering method. Here, the soldering method is carried by a process temperature below 450° C. and the at least one electronic unit connected to the at least one conductor of the contacting surface in an electrically conductive manner. On the contacting surface, multiple electronic units—for example transistors, transducers or capacitors—which are interconnected through the contacting surface can also be fixed. A so-called SMD component is substantially produced in this manner.

For protecting the at least one electronic unit, a protective coating can be advantageously applied to the cooling plate after the fixing of the contacting surface. The protective coating can protect the at least one electronic unit from corrosion and electrically insulate the same towards the outside. The protective coating preferably consists of parylenes, which are chemically resistant and electrically insulating.

Through the method according to the invention, the contacting surface is fixed to the cooling plate over a large area with a reduced expenditure. The process temperature in this case is below 250° C. so that internal stresses and thus the developing of damage in the cooling device are advantageously avoided because of this. By way of the method according to the invention, the cooling device can, furthermore, be produced cost-effectively, quickly and with reduced expenditure.

Further important features and advantages of the invention are obtained from the subclaims, from the drawings and from the associated figure description by way of the drawings.

It is to be understood that the features mentioned above and still to be explained in the following cannot only be used in the respective combination stated but also in other combinations or by themselves without leaving the scope of the present invention.

Preferred exemplary embodiments of the invention are shown in the drawings and are explained in more detail in the following description, wherein same reference numbers relate to same or similar or functionally same components.

### BRIEF DESCRIPTION OF THE DRAWINGS

It shows, in each case schematically

FIG. 1 a sectional representation of a cooling device according to the invention with a ceramic plate coated on both sides;

FIG. 2 a sectional representation of a cooling device according to the invention with a ceramic plate coated on one side;

FIG. 3 a sectional representation of a cooling device according to the invention with a contacting surface in the form of a conductor support;

FIG. 4 a sectional representation of a cooling device according to the invention with a directly applied contacting surface.

### DETAILED DESCRIPTION

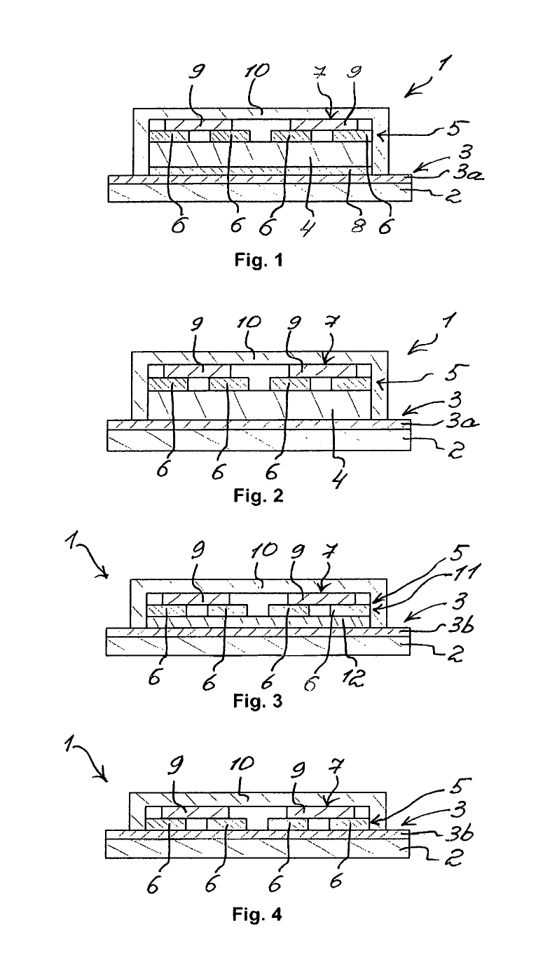

FIG. 1 shows a sectional representation of a cooling device 1 according to the invention with a heat-dissipating cooling plate 2. On the cooling plate 2, an organic intermediate layer 3 is fixed in a firmly bonded manner, which in this exemplary embodiment is an adhesive layer 3a. On the adhesive layer 3a, a ceramic plate 4 is fixed. A contacting surface 5 comprises multiple conductors 6 for fixing and for contacting power electronics 7 and is fixed to the ceramic plate 4 in a firmly bonded manner. The ceramic plate 4 comprises a copper layer 8 facing away from the contacting surface 5 and together with the contacting surface 5 corresponds to a conventional DCB substrate. The ceramic plate 4 is fixable to the cooling plate 2 by means of the adhesive layer 3a at a process temperature below 250° C., as a result of which internal stresses in the ceramic plate 4, in the copper layer 8 and in the contacting surface 5 are advantageously avoided.

On the contacting surface 5 with the conductors 6, multiple electronic units 9 of the power electronics 7 are fixed. The electronic units 9 and the contacting surface 5 are electrically insulated from the cooling plate 2 by the ceramic plate 4, so that no leakage currents are created in the cooling device 1.

For protecting the electronic units 9, the cooling device 1 in this exemplary embodiment comprises a protective coating 10 preferably of parylene which protects the electronic units 9 from mechanical damage and external influences. Alternatively, the cooling device 1 can also be produced without the protective coating 10.

In FIG. 2, a sectional representation of the cooling device 1 according to the invention is shown with a deviating construction. In this exemplary embodiment, the ceramic plate 4 does not have a copper layer 8 and is directly fixed to the adhesive layer 3a. Compared with the ceramic plate 4 with the copper layer 8 shown in FIG. 1, the material and consequently also the production costs can be reduced here. To further reduce the production costs, the cooling device 1 can be produced for example even without the protective coating 10.

FIG. 3 shows a sectional view of the cooling device 1 according to the invention, wherein the organic intermediate layer 3 in this exemplary embodiment preferably is an insulating layer 3b consisting of parylene. Through the insulating layer 3b, the contacting surface 5 is electrically insulated from the cooling plate 2. The contacting surface 5 in this exemplary embodiment is a conductor support 11, which is produced from a thick copper film for example by way of a stamping method. The conductor support 11 is fixed to the insulating layer 3b by an adhesive coating 12. Through the adhesive coating 3b, additional layers—and in particular the ceramic plate 4—are no longer required and the cooling device 1 is constructed in a more compact manner. The electronic units 9 of the power electronics 7 are fixed to the contacting surface 5 for example by way of a soldering method below 450° C. and in this exemplary embodiment are protected by the protective coating 10 from mechanical damage and external influences.

FIG. 4 shows the cooling device 1 according to the invention with the insulating layer 3b, wherein the contacting surface 5 is fixed to the insulating layer 3b by a wet coating method or by a physical vapour deposition. Compared with the cooling device 1 shown in FIG. 3, the adhesive coating 12 is no longer required here and the cooling device 1 is constructed in an even more compact manner. In order to design the cooling device 1 in an even more compact manner, the cooling device 1 can be embodied for example without the protective coating 10.

In the cooling device 1 according to the invention, the contacting surface 5 with the power electronics 7 is fixed to the cooling plate 2 over a large area with reduced expenditure. The cooling device 1 according to the invention makes possible an efficient dissipation of the heat generated in the power electronics 7 and can, furthermore, be produced in a more compact, cost-effective and quicker manner.

1. A cooling device for cooling power electronics, comprising:
a heat-dissipating cooling plate;
a contacting surface including multiple conductors arranged thereon configured to fix and contact a power electronics, the contacting surface arranged on the heat-dissipating cooling plate;
the contacting surface electrically insulated from the heat-dissipating cooling plate;
wherein between the heat-dissipating cooling plate and the contacting surface at least one organic intermediate layer is arranged, the at least one organic intermediate layer fixed to the heat-dissipating cooling plate in a firmly bonded manner.

2. The cooling device according to claim 1, further comprising:
a ceramic plate;
the at least one organic intermediate layer structured as an adhesive layer; and
the ceramic plate fixed to the adhesive layer, wherein the contacting surface is fixed to the ceramic plate in a firmly bonded manner and is electrically insulated from the heat-dissipating cooling plate via the ceramic plate.

3. The cooling device according to claim 2, wherein the ceramic plate includes a copper layer facing away from the contacting surface, and wherein the ceramic plate with the copper layer is fixed to the adhesive layer.

4. The cooling device according to claim 1, wherein:
the at least one organic intermediate layer is an insulating layer; and
the contacting surface is electrically insulated from the heat-dissipating cooling plate via the insulating layer.

5. The cooling device according to claim 4, wherein the insulating layer includes parylene.

6. The cooling device according to claim 4, wherein at least one of:
the contacting surface is fixed to the insulating layer; and
the contacting surface is a conductor support and is fixed to the insulating layer via an organic adhesive coating.

7. The cooling device according to claim 4, wherein at least one of the heat-dissipating cooling plate and the insulating layer has a three-dimensional structure.

8. The cooling device according to claim 1, further comprising at least one electronic unit coupled on the contacting surface.

9. The cooling device according to claim 1, further comprising a protective coating.

10. A method for producing a cooling device comprising:
applying at least one organic intermediate layer to a heat-dissipating cooling plate; and
subsequently coupling a contacting surface including multiple conductors configured to fix and contact a power electronics to the heat-dissipating cooling plate such that i) the at least one organic intermediate layer is arranged between the heat-dissipating cooling plate and the contacting surface and ii) the contacting surface is electrically insulated from the heat-dissipating cooling plate.

11. The method according to claim 10, wherein:
the applying at least one organic intermediate layer includes applying an adhesive layer to the heat-dissipating cooling plate; and
the coupling the contacting surface to the heat-dissipating cooling plate includes coupling a ceramic plate with the contacting surface to the heat-dissipating cooling plate via the adhesive layer and applying a heat supply.

12. The method according to claim 10, wherein:
the applying the at least one organic intermediate layer includes applying an insulating layer to the heat-dissipating cooling plate; and
the contacting surface is electrically insulated from the heat-dissipating cooling plate via the insulating layer.

13. The method according to claim 12, wherein the applying the insulating layer includes applying the insulating layer to the heat-dissipating cooling plate via chemical vacuum vapour deposition.

14. The method according to claim 13, further comprising:
arranging a pattern mask on the heat-dissipating cooling plate prior to the applying the insulating layer; and
removing the pattern mask from the heat-dissipating cooling plate after the applying the insulating layer.

15. The method according to claim 13, further comprising structuring the insulating layer after the applying the insulating layer.

16. The method according to claim 12, wherein the coupling the contacting surface to the heat-dissipating cooling plate includes coupling the contacting surface to the insulating layer via one of a wet coating process and physical vapour deposition.

17. The method according to claim 12, wherein the contacting surface is a conductor support, and wherein the coupling the contacting surface to the heat-dissipating cooling plate includes coupling the conductor support to the insulating layer via an organic adhesive coating.

18. The method according to claim 17, further comprising:
pre-treating the insulating layer; and
applying the adhesive coating on the insulating layer after pre-treating the insulating layer.

19. The method according to claim 10, further comprising coupling at least one electronic unit to the contacting surface prior to the coupling the contacting surface to the heat-dissipating cooling plate.

20. The method according to claim 19, further comprising applying a protective coating to the heat-dissipating cooling plate after the coupling the contacting surface to the heat-dissipating cooling plate.
